(19) United States
(12) Patent Application Publication
(10) Pub. No.: US 2026/0254198 A1
(43) Pub. Date: Aug. 27, 2026

(54) Device and method for frequency stabilization of a laser

(71) Applicant: FERDINAND-BRAUN-INSTITUT GGMBH LEIBNIZ-INSTITUT FÜR HÖCHSTFREQUENZTECHNIK, Berlin (DE)

(72) Inventors: Janpeter HIRSCH, Berlin (DE); Max SCHIEMANGK, Berlin (DE); Andreas WICHT, Berlin (DE)

(73) Assignee: FERDINAND-BRAUN-INSTITUT GGMBH LEIBNIZ-INSTITUT FÜR HÖCHSTFREQUENZTECHNIK, Berlin (DE)

(21) Appl. No.: 18/992,232

(22) PCT Filed: Jul. 7, 2023
(86) PCT No.: PCT/EP2023/068884

§ 371 Date: Jan. 8, 2025

(30) Foreign Application Priority Data
Jul. 8, 2022 (DE) 10 2022 117 050.0

(51) Int. Cl. H01S 5/0687; H01S 5/02325; H01S 5/14

(52) U.S. Cl. CPC H01S 5/0687; H01S 5/02325; H01S 5/141

(57) ABSTRACT

The present invention relates to a device and a method for frequency stabilization of a laser, in particular to a device and a method for frequency stabilization of a laser based on the spectroscopy of a temperature-stabilized volume Bragg grating (VBG). A device according to the invention for frequency stabilization of a laser (D1, D2) comprises a beam path for injecting laser radiation emitted by the laser (D1, D2) into a frequency-selective element, wherein the frequency-selective element is temperature-controlled, wherein the frequency-selective element is a volume Bragg grating, VBG, (G1) with a plurality of grating structures (E) and, prior to injection of the laser radiation into the VBG (G1) via an input facet, a proportion of the laser radiation is branched off into a reference beam and the proportion of the laser radiation injected into the VBG (G1) forms a measurement beam.

The present invention relates to a device and a method for frequency stabilization of a laser, in particular to a device and a method for frequency stabilization of a laser based on the spectroscopy of a temperature-stabilized volume Bragg grating (VBG).

### PRIOR ART

In telecommunications and quantum sensor applications, there is a need for frequency references for stabilizing lasers with a specific performance profile. In particular for applications on mobile platforms in space such frequency references must be as compact as possible, tunable without mode hopping and stable over the long term, wherein a (reproducible) frequency accuracy of around 50 MHz must be achieved. Corresponding frequency reference modules for implementing space-qualified frequency references having these characteristics are as yet unknown in the prior art.

Prior art frequency references are typically based on the spectroscopy of a fiber Bragg grating (FBG) and are known to the skilled person, for example, from Sotor et al. (J. Z. Sotor, A. J. Antonczak and K. M. Abramski, “Fiber Bragg Gratings as References for Frequency Stabilization of Microchip Laser”, 2006 International Conference on Transparent Optical Networks, 2006, pp. 167-169). As shown in the figure taken from Sotor et al. and reproduced in FIG. 1, the laser radiation is here injected into an FBG via an optical waveguide-based beam splitter. The diffracted signal is split via an optical waveguide-based beam splitter and used with the transmitted signal to generate a fault signal for frequency stabilization of a laser. In order to ensure the thermal stability of the frequency-selective element, which is required for elevated frequency stability of the laser, the FBG is surrounded by an athermal housing.

However, an optical waveguide-based spectroscopy approach has significant disadvantages. In particular, the properties of optical waveguides can change, in particular in long-term operation, under the influence of irradiation, mechanical stress and temperature fluctuations. This leads to inadmissible measurement errors in high-sensitivity sensor applications. When using a waveguide-based beam splitter, these influences also result in temperature-and polarization dependence of the splitting ratio of the waveguide-based beam splitter. Fluctuations in the splitting ratio result in an incorrect interpretation of the spectroscopy signal during ongoing operation. These systematic errors result in frequency errors. Using an athermal housing is intended to achieve thermal decoupling of the FBG in order to achieve high frequency stability. However, this approach makes it impossible to tune the frequency of the grating by controlling its temperature. FBG-based frequency stabilization is thus unsuitable for applications on mobile platforms in space and other stabilization concepts must be used for this purpose.

### DISCLOSURE OF THE INVENTION

It is therefore an object of the present invention to provide a device for frequency stabilization of a laser which enables sufficient laser stability for the previously mentioned mobile applications in space with the above-mentioned performance profile. Furthermore, a corresponding method for frequency stabilization of a laser is to be provided.

These objects are achieved according to the invention by the features of Claims 1, 13 and 15. Advantageous configurations of the invention are recited in the dependent claims. The features individually listed in the claims can be combined with one another in a technically meaningful way and can be supplemented by explanatory facts from the description and/or details from the figures, wherein further variant embodiments of the invention are indicated.

A first aspect of the invention relates to a device for frequency stabilization of a laser comprising a beam path for injecting laser radiation emitted by the laser into a frequency-selective element, wherein the frequency-selective element is temperature-controlled, wherein the frequency-selective element is a volume Bragg grating, VBG, with a plurality of grating structures and, prior to injection of the laser radiation into the VBG via an input facet, a proportion of the laser radiation is branched off into a reference beam and the proportion of the laser radiation injected into the VBG forms a measurement beam.

A beam path is in particular taken to mean guidance of the laser radiation as a “free beam”, i.e., the laser radiation is not injected into the frequency-selective element by way of an optical fiber or a waveguide, but instead, for example, as a freely propagating Gaussian beam (free beam).

The temperature of the frequency-selective element is controllable, i.e., it can be varied relative to the environment by appropriate control. Since the filter frequency of a frequency-selective element is generally dependent on its temperature, temperature control of the frequency-selective element thus also includes controllability of the filter frequency (center frequency) of the frequency-selective element. A Peltier element is advantageously used for rapid temperature control of the VBG as, unlike a heating element in conjunction with additional cooling, it also inherently enables active cooling. When a heating element is used, however, the thermal connection of the VBG must be specially optimized for fast and effective cooling.

A VBG is a specific kind of optical grating. In contrast with mechanical gratings (“ruled gratings”) or holographically generated planar gratings (“holographic gratings”), which typically take the form of surface gratings, VBGs are generally “thick gratings” in the interior of a material volume. VBGs have a plurality of grating structures arranged one behind the other. For the purposes of the present invention, the individual reflective layers of a grating are denoted grating structures. These may be, for example, the individual grating planes of a VBG consisting of a plurality of grating planes arranged one behind the other in a suitable material. The individual grating structures may, however, also have non-planar forms, for example curved surface shapes. The spacing of the grating structures from one another may vary to provide a grating with a broad spectral distribution (termed “chirped grating”). A VBG can also comprise a plurality of gratings that are separate from one another or at least in part merge into one another and have corresponding grating structures. VBGs are typically generated holographically and the corresponding filter elements are then also denoted volume-holographic Bragg gratings (VHGs). VBG structures can, however, also be generated non-holographically, for example by inscribing fs laser pulses in glass via a phase mask.

The VBG preferably takes the form of a volume-holographically generated Bragg grating in a photothermorefractive glass. In preferred embodiments, it is also possible to use a volume-holographic Bragg grating based on dichromatic gelatin, photopolymers, photorefractive crystals or a silver halide emulsion as the VBG medium. One important criterion for applications on mobile platforms in space is in particular the long-term stability of the VBG and in particular low susceptibility to irradiation, mechanical stress and temperature fluctuations as well as aging effects.

According to the invention, a proportion of the laser radiation is branched off into a reference beam prior to injection of the laser radiation into the VBG, which takes place via an input facet of the VBG. The phrase “prior to injection” should be understood in relation to positions along the beam path; branching off can therefore also be carried out temporally in parallel with the injection, i.e., on or during the physical process of injection. Branching off the reference beam may to this end in particular be carried out by direct reflection at the input facet of the VBG on injection. Alternatively, the reference beam can also be branched off from the free beam directed onto the VGB by a beam splitter arranged upstream of the VBG. The reference beam can be detected with an appropriate reference detector. The proportion of the laser radiation injected into the VBG, on the other hand, forms a measurement beam. The measurement beam may preferably be detected either as a transmitted measurement beam downstream of the VBG or as a diffracted measurement beam upstream of the VBG. Both the transmitted and the diffracted measurement beams may also be repeatedly reflected within the VBG (e.g., at the outer faces of the VBG).

The VBG is preferably arranged in a Littrow configuration. In such a configuration, the laser radiation impinges perpendicularly on the grating structures of the VBG. If the VBG is operated in a Littrow configuration, the value of the frequency of the device according to the invention (center frequency of the VBG) is insensitive to tilting of the incident laser beam in the first order.

The input facet of the VBG preferably has an angle other than 90° to the beam axis of the incident laser radiation and/or an angle to the grating structures of the VBG. If the input facet of the VBG has an angle other than 90° to the beam axis of the incident laser radiation, the reflected proportion of the incident laser radiation at the input facet of the VBG is directed in a direction other than the direction of incidence. This means that there is no direct back reflection into the laser, which can lead to interference. Furthermore, a proportion of the laser beam can be branched off into a separate reference beam via the reflection immediately prior to injection into the VBG. The spatial separation of the incident beam and the beam reflected by the input facet makes it possible to dispense with an additional beam splitter. Dielectric beam splitters namely have highly reflective coatings with properties that are temperature-dependent and change over time (aging effects). Some of the incoming laser radiation is particularly preferably branched off by Fresnel reflection at the input facet of the VBG. Depending on the refractive index of the VBG medium and the angle of incidence, a specific angle can be set between the laser radiation and the grating structures of the VBG. In particular, this allows the VBG to be optimally adapted to a specific Littrow configuration, wherein, in the Littrow configuration, the beam reflected by the input facet is not reflected in the direction of the incoming beam.

The VBG preferably comprises a mounting surface, a top surface opposite the mounting surface, and two side surfaces connecting the mounting surface and the top surface, wherein a grating vector of the VBG and the top surface are configured parallel to the mounting surface and/or the side surfaces are configured parallel to one another. The VBG can additionally comprise a front surface connecting the mounting surface and the top surface through which the laser radiation preferably enters (input facet), and a rear surface connecting the mounting surface and the top surface that is opposite the input facet. The side surfaces of the VBG are preferably oriented parallel to one another with a tolerance of ±100′, more preferably of ±10′, in order to minimize the volume of the VBG. The grating vector, which is orthogonal to the grating structures (e.g., planar or slightly curved surfaces with identical refractive indices), as well as the top surface are preferably oriented parallel to the mounting surface of the VBG with a tolerance ±40′, more preferably of ±4′, in order to simplify the integration process of the device according to the invention. The angle between the grating vector of the VBG and the beam axis of the refracted beam (measurement beam after injection into the VBG) preferably has a tolerance of ±40′, more preferably of ±4′. A tighter tolerance of the angle between the grating vector of the VBG and the beam axis of the refracted beam allows greater latitude during the integration process.

The angle between the beam axis of the incident beam and the input facet of the VBG preferably amounts to ±10°, more preferably ±1°. The input facet of the VBG preferably has an angle of 45°±1° to the beam axis of the incident light beam. Using a 45° angle between the beam axis of the incident beam and the input facet of the VBG simplifies mechanical integration, whereas a tighter tolerance of the angle between the beam axis of the incident beam and the input facet of the VBG permits a more predictable detector signal level due to the angular dependence of Fresnel reflection and thus the use of smaller and faster detectors.

In a further preferred embodiment, the angle between the beam axis of the incident beam and the input facet of the VBG is not 45°, but instead assumes another value, wherein the incident beam and the beam reflected at the input facet are spatially separate. In a further preferred embodiment, the beam incident on the input facet of the VBG and the beam reflected at the input facet overlap spatially. In this case, the reference beam can be generated by a beam splitter that is arranged upstream of the VBG.

The VBG preferably takes the form of a parallelepiped and the grating structures of the VBG are in each case arranged perpendicular to the mounting surface, the top surface and the side surfaces of the VBG. In this case, not only is the integration process of the device according to the invention simplified but also the space it requires is reduced and so too its thermal load. A parallelepiped can itself provide the surface bevel relative to the grating structures that is required for Fresnel reflection at the input facet.

The reference beam is preferably branched off at a surface of the VBG (preferably via Fresnel reflection at the input facet) or a beam splitter arranged upstream of the VBG. In the case of Fresnel reflection, it is possible to dispense with a dielectric coating on the input facet to reduce reflection. Dispensing with a dielectric coating on the input facet of the VBG avoids temperature and aging effects on reflection and transmission.

The device according to the invention preferably further comprises a reference detector set up to determine an intensity of the reference beam and a measurement detector set up to determine an intensity of the measurement beam, wherein the intensity of the measurement beam is determined after passage through the VBG. The measurement beam can be reflected repeatedly at the outer surfaces within the VBG. In particular, the measurement beam can pass through the VBG once, twice or multiple times. The measurement detector preferably detects a signal (transmission signal) transmitted by the VBG. Alternatively, however, a beam of light diffracted by the VBG can also be detected by the measurement detector (diffraction signal). The detectors are preferably photodiodes.

The device according to the invention preferably further comprises a first electronic circuit for deriving a fault signal from a reference signal of the reference detector and a measurement signal of the measurement detector. A fault signal is taken to mean a signal with a functional dependency that correlates with the control deviation. Typically, the fault signal has a characteristic operating point (e.g., at zero crossover) that is suitable for a control circuit.

Instead of using the reference signal and a transmission signal for deriving the fault signal, it is also possible to use the reference signal and a diffraction signal. In further embodiments, a transmission signal and a diffraction signal, or the reference signal, a transmission signal, and a diffraction signal can be used to derive a fault signal. Furthermore, a fault signal can be derived using only a diffraction signal or only a transmission signal, wherein a constant input level is, however, required in both cases.

The VBG is preferably decoupled thermally from its surroundings by a grating housing. An appropriate grating housing can enable enhanced thermal and optical insulation of the VBG. The grating housing can be connected to an optical bench on which the VBG is arranged with other components. The grating housing may include temperature stabilization. Such an embodiment enables a smaller temperature gradient of the surroundings of the VBG of relevance to heat radiation.

The VBG is preferably arranged with other components in a module housing. In particular, the VBG can be arranged in the module housing with other components (e.g., mirrors, polarizers, and/or an optical bench) with or without an additional grating housing. Such an embodiment enables better thermal and acoustic insulation of the VBG. The module housing can be thermally decoupled from its surroundings and include temperature stabilization.

At least one device for cooling and/or heating is preferably used for temperature stabilization of the VBG. A device for cooling and/or heating may preferably comprise a Peltier element or a heating element. When a heating element is used, the thermal connection of the VBG (or of elements connected thereto) may be specially optimized for fast and effective cooling. Cooling may, for example, involve radiative cooling into space. It is further preferable for the detectors used for signal acquisition according to the invention to be arranged with the VBG on a common Peltier element or a common appropriately thermally connected platform. Such an embodiment makes it possible to reduce sensitivity to beam misalignment and so increase the accuracy of the device according to the invention.

The stated embodiments can advantageously be combined with one another in their entirety or in part.

A second aspect of the present invention relates to a method for frequency stabilization of a laser using a device according to the invention, wherein a fault signal is derived from an intensity of the reference beam and an intensity of the measurement beam after passage (at least once) through the VBG, and the frequency of the laser is stabilized with the fault signal via a control loop.

In particular, the temperature of the device according to the invention can be controlled via a device for cooling and/or heating. This control may relate to the VBG locally or to other components, such as for example an optical bench on which the VBG is arranged with other components. It is likewise possible to combine a plurality of temperature control approaches. Temperature stabilization of the optical bench increases the accuracy of the method according to the invention.

The laser radiation spectrally filtered by the VBG is preferably reinjected into the laser to form an extended resonator for the laser. In particular, a frequency-stabilized diode laser with an extended resonator (“extended-cavity diode laser”, ECDL) can be implemented in this way. An associated control circuit can then be used, for example, to control the injection current or the temperature of the laser in order to adjust and stabilize laser frequency.

A third aspect relates to a method for measuring the frequency of a laser using a device according to the invention, wherein a fault signal is derived from an intensity of the reference beam and an intensity of the measurement beam after passage (at least once) through the VBG, the temperature of the VBG is adjusted with the fault signal via a control loop in such a way that a Bragg frequency (center frequency) of the VBG corresponds to the frequency of the laser except for an optionally selected, signed frequency difference, and the frequency of the laser is determined by way of a known association with the adjusted temperature of the VBG. The Bragg frequency (center frequency) of the VBG can thus also be directly adjusted to the frequency of the laser.

The method for measuring the frequency of a laser and the method according to the invention for frequency stabilization of a laser differ substantially only in terms of the controlled variable, but are otherwise based on a common inventive concept. While, for the purpose of laser frequency stabilization, it is possible to use the fault value derived according to the invention to control the temperature and/or the injection current of the laser in order to adjust and stabilize a specific laser frequency, for the purpose of laser frequency measurement it is possible to stabilize the temperature of the VBG with the assistance of temperature control in such a way that a Bragg frequency (center frequency) of the VBG corresponds to the frequency of the laser except for an optionally selected, signed frequency difference. On the basis of the temperature of the VBG adjusted or established via a temperature sensor, the frequency of the laser can then be determined via a known association and for example displayed on a display device.

In addition, further preferred configurations of the method according to the invention are directly revealed by the features stated in the description in relation to the device according to the invention.

The present invention can be used in quantum sensors for more quickly and reliably stabilizing lasers to a desired wavelength, for example of an atomic transition. The device according to the invention can consequently make it easier, for example, for two satellites to establish communication (acquire a lock) for optical satellite communication.

While in the prior art the light signals are guided in optical waveguides, in the present invention they are preferably propagated in free space. The present invention is in particular distinguished by the following structural differences:
1. A VBG is used instead of an FBG as the frequency-selective element.
2. An optical waveguide-based beam splitter is not used to separate the light signals upstream of the FBG. Some of the incident light signal is preferably branched off from the remainder of the signal by a Fresnel reflection at the input facet of the VBG. For this purpose, the input facet of the VBG can be arranged at an angle to the incident beam such that the Fresnel reflection and the incoming beam are spatially separated from one another. The fault signal can preferably be derived from the transmitted and the branched off incident light signal.
3. The VBG can be arranged on an optical bench or in general on a suitable carrier, the temperature of which can be stabilized to a predetermined value with a suitable device for cooling and/or heating and a temperature sensor.

In comparison with the prior art, the device according to the invention is distinctly more resistant to irradiation, mechanical stress and changes in temperature, since no optical waveguide components are used at the points that are particularly critical for measurement accuracy Preferred branching off of the reference beam by Fresnel reflection makes it possible to make the splitting ratio largely independent of temperature influences. By using a Peltier element and dispensing with an athermal housing, the frequency of the VBG can be tuned directly via temperature. By miniaturizing the device and appropriately shaping the VBG, it is possible to achieve greater mechanical stability combined with a lower weight and a reduced form factor. An optional module housing can very largely shield the device according to the invention from acoustic and thermal influences. It is furthermore possible to achieve a high frequency accuracy combined at the same time with the option of frequency tuning by staggered temperature stabilization of the VBG for example with the assistance of a Peltier element under the VBG, a grating housing around the Peltier element, a further Peltier element for stabilizing an optical bench and a module housing around the optical bench.

Further preferred configurations of the invention are revealed by the features mentioned in the respective subclaims.

The various embodiments of the invention set out in this application can advantageously be combined with one another unless otherwise specified.

### BRIEF DESCRIPTION OF THE DRAWINGS

The invention and the technical context are explained in greater detail below with reference to the appended figures. It should be noted that it is not intended for the invention to be limited by the recited exemplary embodiments. In particular, unless explicitly stated otherwise, it is also possible to extract subaspects of the subject matter explained in the figures and combine them with other components and insights from the present description. In the drawings:

FIG. 1 shows a schematic representation of a conventional device for frequency stabilization of a laser according to the prior art (from Sotor et al.);

FIG. 2 shows a schematic representation of a first embodiment of a device according to the invention for frequency stabilization of a laser;

FIG. 3 shows a schematic representation of a second embodiment of a device according to the invention for frequency stabilization of a laser;

FIG. 4 shows a schematic representation of a third embodiment of a device according to the invention for frequency stabilization of a laser;

FIG. 5 shows a schematic representation of a fourth embodiment of a device according to the invention for frequency stabilization of a laser;

FIG. 6 shows a schematic representation of a VBG geometry according to the invention;

FIG. 7 shows a schematic representation for implementing a first embodiment of a method according to the invention for frequency stabilization of a laser using a device according to FIG. 2;

FIG. 8 shows a schematic representation of the signals corresponding to the embodiment according to FIG. 7;

FIG. 9 shows a schematic representation for implementing a second embodiment of a method according to the invention for frequency stabilization of a laser using a device according to FIG. 2;

FIG. 10 shows a schematic representation for implementing a third embodiment of a method according to the invention for frequency stabilization of a laser using a device according to FIG. 2;

FIG. 11 shows a schematic representation for implementing an embodiment of a method according to the invention for measuring the frequency of a laser using a device according to FIG. 2;

FIG. 12 shows a schematic representation of the signals according to FIG. 11; and

FIG. 13 shows a schematic representation of an association of the temperature of the VBG with the frequency of the laser according to FIG. 11.

### DETAILED DESCRIPTION OF THE DRAWINGS

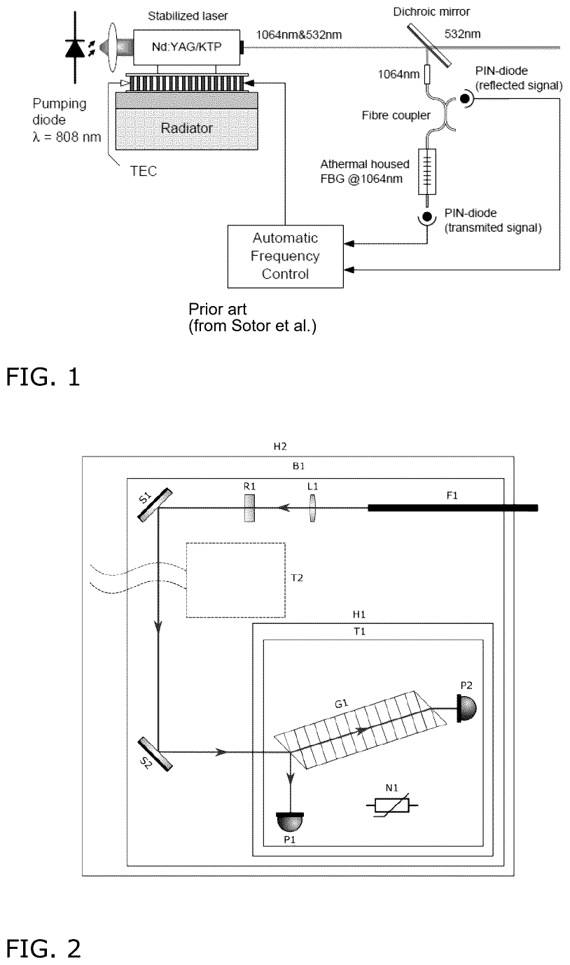

FIG. 1 shows a schematic representation of a conventional device for frequency stabilization of a laser according to the prior art (from Sotor et al.). The laser (“stabilized laser”) comprises a temperature-controlled laser crystal (Nd:YAG/KTP) that is temperature-controlled by way of a Peltier element (TEC—“thermoelectric cooler”) and emits double resonantly at emission wavelengths of 1064 nm and 532 nm. The laser crystal is pumped via a diode laser (“pumping diode”) with an emission wavelength at 808 nm. The proportion of the radiation at 1064 nm is branched off via a dichroic beam splitter (“dichroic mirror”) and injected via a fiber coupler into an FBG arranged within an athermal housing. The intensity of the diffracted radiation component (“reflected signal”) and of the radiation component transmitted by the FBG (“transmitted signal”) is determined via appropriately arranged PIN photodiodes (“PIN diodes”) and both signals are supplied to an electronic circuit for controlling the temperature of the laser crystal (“automatic frequency control”). The quality of the laser frequency stabilization here depends primarily on the stability of the FBG and the associated fiber portions within the device.

FIG. 2 shows a schematic representation of a first embodiment of a device according to the invention for frequency stabilization of a laser. A light signal is here injected into the device via a polarization-maintaining single-mode optical waveguide (PMSF) F1. PMSF F1 permits straightforward integration of the device according to the invention into existing optical systems. The injected light signal is collimated with an optical system L1. A polarizer R1 ensures that only s-polarized light is directed onto the VBG G1 with mirrors S1 and S2. The beam of light can be directed such that, as shown in FIG. 6, the VBG G1 can be operated in a Littrow configuration (i.e., perpendicular incidence of the light onto the grating structures E) with a tolerance of ±1°. The polarizer R1 can prevent any potential polarization fluctuations that can lead to systematic measurement errors. Beam guidance via the two mirrors S1 and S2 offers greater latitude when positioning the VBG than when just one or no mirror is used.

The VBG G1 can be attached to a temperature sensor N1 for temperature stabilization, for example to a first device for cooling and/or heating T1. Reference detector P1 and measurement detector P2 can likewise be attached to the device for cooling and/or heating T1 in order to ensure stable beam alignment. PMSF F1, optical system L1, polarizer R1, mirrors S1 and S2, and the device for cooling and/or heating T1 are preferably adhesively bonded to a common optical bench B1. A grating housing H1 can be thermally conductively connected to optical bench B1 to improve the temperature stability of the device according to the invention. The optical bench B1 can likewise be stabilized to a desired temperature with a second device for cooling and/or heating T2.

An optional module housing H2 can be used to shield the optical bench B1 from thermal and acoustic interference from the surroundings. Optical system L1, polarizer R1, mirrors S1 and S2, and VBG G1 preferably comprise microoptical components. It is preferred to use microoptical components due to the associated smaller form factor, reduced weight and increased mechanical stability of the device according to the invention. Devices for cooling and/or heating T1, T2 may preferably comprise Peltier elements or heating elements.

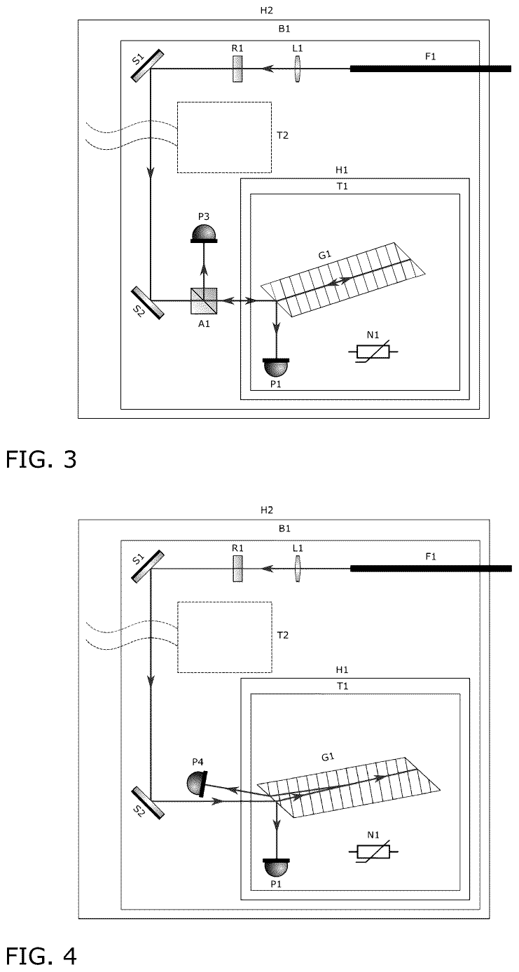

FIG. 3 shows a schematic representation of a second embodiment of a device according to the invention for frequency stabilization of a laser. The representation shown largely corresponds to FIG. 2 so the reference signs are applied correspondingly. In this embodiment, the intensity of the beam of light diffracted by the VBG G1 is determined with the measurement detector P3 (diffraction signal). A fault signal can thus be generated using the reference signal and a diffraction signal instead of the reference signal and a direct transmission signal. The intensity of the diffracted beam can be determined with the measurement detector P3 after reflection at a beam splitter A1 upstream of the VBG G1.

FIG. 4 shows a schematic representation of a third embodiment of a device according to the invention for frequency stabilization of a laser. The representation shown largely corresponds to FIG. 3 so the reference signs are applied correspondingly. If the incident and diffracted beams do not overlap spatially, the additional beam splitter A1 upstream of the VBG G1 can be dispensed with and the intensity of the diffracted beam can instead also be determined directly with a measurement detector P4.

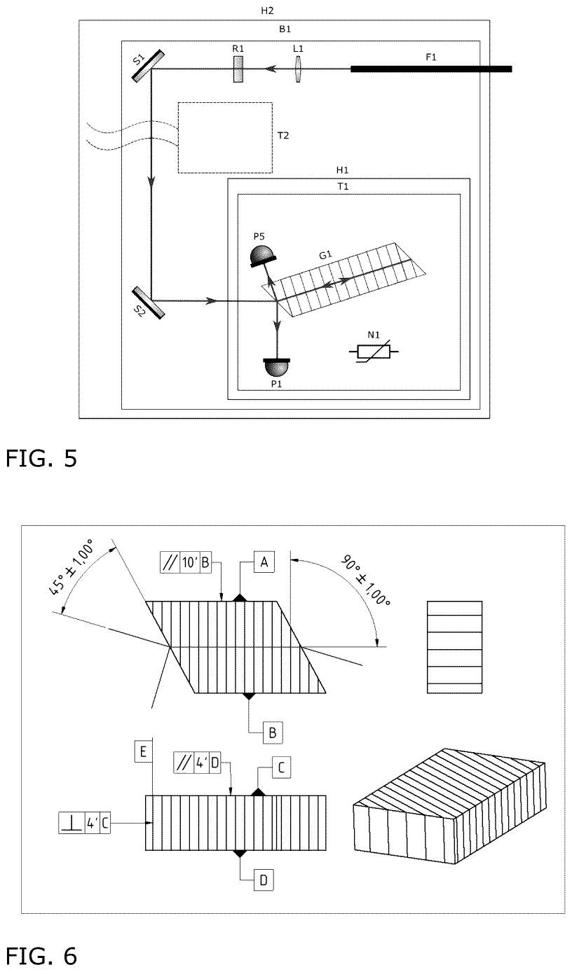

FIG. 5 shows a schematic representation of a fourth embodiment of a device according to the invention for frequency stabilization of a laser. The representation shown largely corresponds to FIG. 4 so the reference signs are applied correspondingly. As an alternative to determining the intensity of the diffracted beam with a measurement detector P4, this can for example also be carried out via a beam coupled out from a side surface (e.g., side surfaces A, B) of the VBG G1 with a measurement detector P5. The corresponding side surface of the VBG G1, from which the diffracted beam emerges after reflection at the input facet must in this case be of optical quality.

FIG. 6 shows a schematic representation of a VBG geometry according to the invention. The input facet of the VBG G1 preferably has an angle of 45°±1° to the beam axis of the incident light beam and is uncoated. The side surfaces A, B of the VBG G1 are preferably oriented parallel to one another with a tolerance of ±10′ in order to minimize the volume of the VBG G1. The grating vector, which is orthogonal to the grating structures E of the same refractive indices, as well as the top surface D are preferably oriented parallel to the mounting surface C of the VBG G1 with a tolerance ±4′ in order to simplify the integration process of the VBG into the device according to the invention. The incident beam of light is preferably Fresnel-reflected at the input facet of the VBG G1.

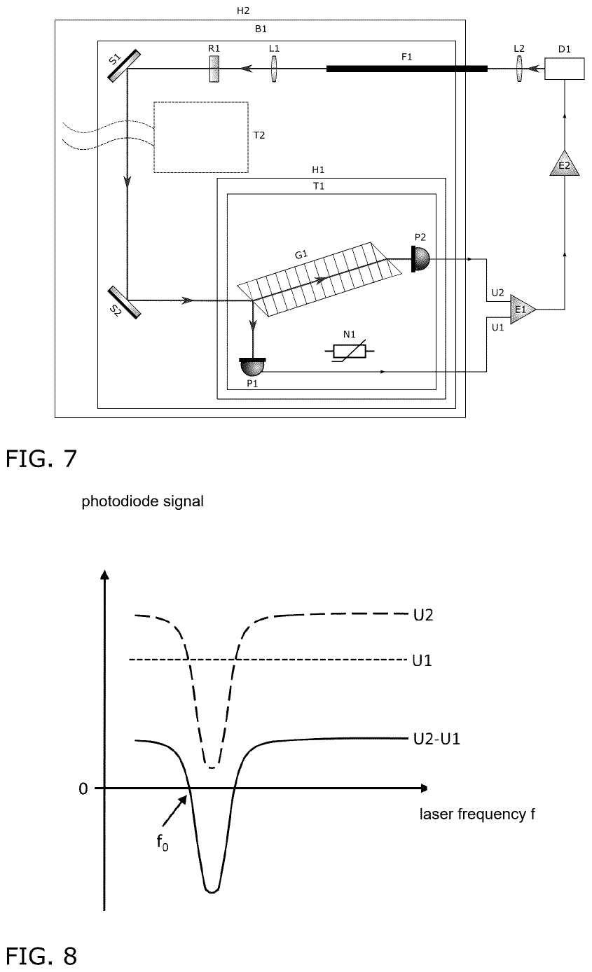

FIG. 7 shows a schematic representation for implementing a first embodiment of a method according to the invention for frequency stabilization of a laser using a device according to FIG. 2. The representation shown largely corresponds to FIG. 2 so the reference signs are applied correspondingly. The light from a laser D1 is injected, here by way of example with the assistance of an optical system L2, into the optical waveguide F1 of a device according to the invention, such that the frequency of the laser D1 can be stabilized by appropriate control.

The beam reflected at the input facet of the VBG G1 shown impinges, for example, on a reference detector P1 (reference signal) that detects the intensity of the reflected beam. A proportion of the light beam incident on the input facet is refracted on entry into the VBG G1. The intensity of the beam transmitted by the VBG G1 can be detected with a measurement detector P2 (transmission signal). A fault signal, which can be used for stabilizing a laser D1 (or for measuring the emission frequency of a laser D1), can be generated from the reference signal U1 of the reference detector P1 and the transmission signal U2 of the measurement detector P2.

To this end, the signals U1 and U2 of the reference detector P1 and of the measurement detector P2 are processed with a suitable electronic circuit E1 to yield a fault signal. The fault signal can then be processed with a suitable electronic circuit E2 and fed back as a control signal to the laser G1 for controlling the frequency of the laser G1 such that the frequency of the laser G1 is adjusted to a defined value f₀.

In the simplest case, the electronic circuit E1 can be implemented such that it amplifies the signals U1 and U2 of the reference detector P1 and the measurement detector P2 proportionally using a suitable proportionality factor and determines the difference between the signals U1 and U2 (see FIG. 8).

FIG. 8 shows a schematic representation of the signals corresponding to the embodiment according to FIG. 7. Exemplary curves of the reference signal U1 of the reference detector P1 and of the transmission signal U2 of the measurement detector P2 (photodiode signals) are plotted against the frequency of the laser D1 (laser frequency f). From this, a differential signal U2-U1 can be determined as a fault signal, wherein the first zero crossover of the fault signal is indicated by way of example in FIG. 8 as a control point for the frequency of laser G1 to a defined value f₀. On activation of the control loop, the frequency of the laser G1 then adjusts to the value f₀ at which the fault signal has a zero crossover with either a positive or (as shown) a negative gradient.

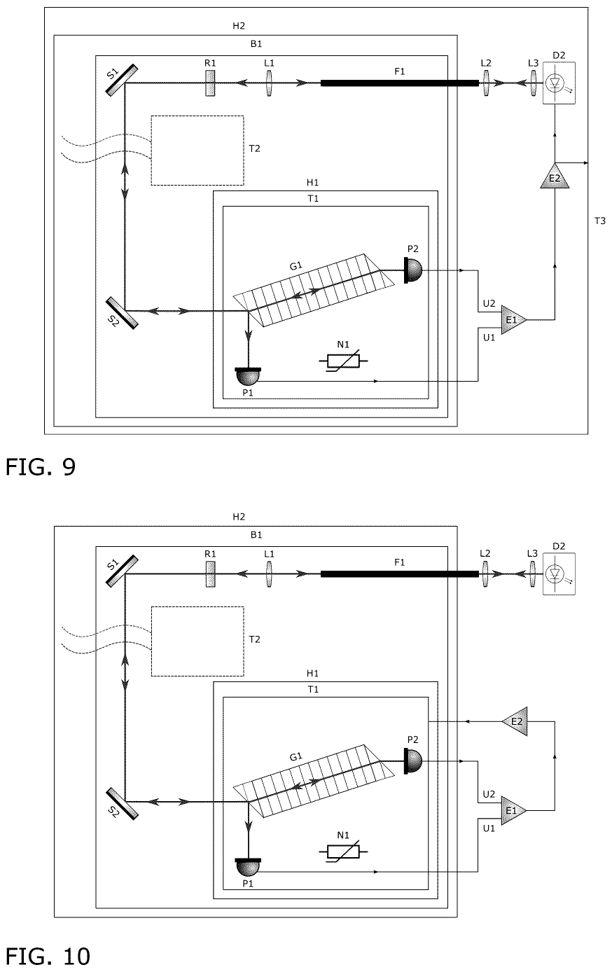

FIG. 9 shows a schematic representation for implementing a second embodiment of a method according to the invention for frequency stabilization of a laser using a device according to FIG. 2. The representation shown largely corresponds to FIG. 2 so the reference signs are applied correspondingly. This is in particular a method for internal frequency stabilization of a diode laser with an extended resonator (“extended-cavity diode laser”, ECDL) with the assistance of a device according to the invention.

The radiation emitted by a laser D2 is collimated with the assistance of an optical collimating system L3 and injected into a device according to the invention with the assistance of the optical system L2. The injected radiation is frequency-selectively diffracted by the VBG G1. The laser setup embodied in this way oscillates at a frequency that corresponds to the frequency of one of the possible longitudinal eigenmodes of the ECDL. The VBG G1, which acts as a spectrally narrow-band reflector, selects one of the possible longitudinal eigenmodes for oscillation. This is typically the longitudinal eigenmode whose frequency is closest to the center frequency of the spectrum of the VBG G1 acting as a reflector. An embodiment of a device according to the invention which is preferred for use of the method described here is one in which the device does not comprise an optical waveguide for injection but rather in which a free beam is injected into the device. This in particular prevents parasitic feedback from the facets of the optical waveguide into the laser D2, which could otherwise interfere with operation of the ECDL.

A change in the air pressure of the surroundings of the laser setup, in the temperature of the laser D2, in the injection current into the laser D2 and/or in the temperature of the laser setup consisting of the laser D2, the optical collimating system L3 and a device according to the invention results in spectral detuning between the frequency of the longitudinal eigenmode of the ECDL and the center frequency of the VBG G1, which acts as a spectrally narrow-band reflector. If this detuning reaches the order of magnitude of the free spectral range of the ECDL, mode hopping occurs, i.e., a change to a different longitudinal eigenmode of the ECDL takes place. This results in an abrupt change in the frequency of laser oscillation.

The method according to the invention for frequency stabilization of a laser can be used to avoid an abrupt change in the frequency of laser oscillation during operation at a constant frequency or in the event of a desired frequency change. To this end, a fault signal is generated from the reference signal U1 of the reference detector P1 and the transmission signal U2 of the measurement detector P2 using a suitable electronic circuit E1. A suitable electronic circuit E2 can then be used to generate therefrom a control signal that controls, for example, the injection current or the temperature of the laser D2 or the temperature of the setup consisting of the laser D2, the optical collimating system L3 and the device according to the invention with the assistance of an appropriate device for cooling and/or heating T3. A combination of these parameters can also be controlled. In this way, the oscillation frequency of the eigenmode of the ECDL is adjusted such that it remains tuned to the frequency f₀ of the device according to the invention. The oscillation frequency of the ECDL thus follows the frequency f₀ of the device according to the invention.

FIG. 10 shows a schematic representation for implementing a third embodiment of a method according to the invention for frequency stabilization of a laser using a device according to FIG. 2. The representation shown largely corresponds to FIG. 9 so the reference signs are applied correspondingly. In contrast to FIG. 9, the control signal generated by the electronic circuit E2 is used to control a device for cooling and/or heating T1 that is directly coupled to the device according to the invention. In this case, the frequency f₀ of the device according to the invention is stabilized to the oscillation frequency of the ECDL.

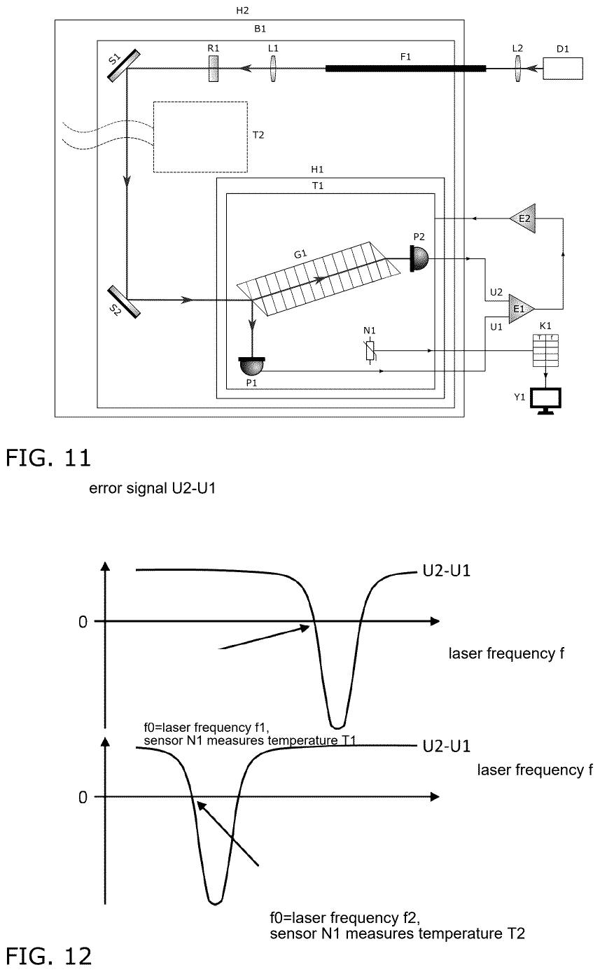

FIG. 11 shows a schematic representation for implementing an embodiment of a method according to the invention for measuring the frequency of a laser using a device according to FIG. 2. The representation shown largely corresponds to FIG. 2 so the reference signs are applied correspondingly. The light from a laser D1 is here injected into the optical waveguide F1 of a device according to the invention, by way of example with the assistance of an optical system L2, such that the device for cooling and/or heating T1 can be driven in such a way that the frequency f₀ of the device according to the invention (corresponding to an optionally selected, signed frequency difference of the center frequency of the VBG or the Bragg frequency) assumes the value f₁ of the frequency of the laser D1. The temperature value measured at temperature sensor N1 adjusted in this way can be assigned a specific value of the frequency of the laser D1.

To this end, the reference signal U1 of the reference detector P1 and the transmission signal U2 of the measurement detector P2 are processed with a suitable electronic circuit E1. The fault signal is processed with the assistance of an electronic circuit E2 in such a way that, as a control signal, it controls a device for cooling and/or heating T1 in such a way that the frequency f₀ of the device according to the invention corresponds to the oscillation frequency f₁ of the laser D1. Depending on the value f₁ of the oscillation frequency of the laser D1, a temperature T characteristic of the value f₁ of the oscillation frequency of the laser D1 is established at the temperature sensor N1. With the assistance of a known association (e.g., a calibration table K1), the value f₁ of the oscillation frequency of the laser D1 can thus be determined from the value of the temperature T at the temperature sensor N1 and displayed on a display device Y1.

FIG. 12 shows a schematic representation of the signals corresponding to FIG. 11. The frequency f₀ of the device according to the invention is stabilized to the value of the frequency of the laser D1 (laser frequency f). Exemplary curves of the differential signal U2-U1 (cf. FIG. 8 for determination) are shown for two different temperatures T₁ and T₂ of the device according to the invention. In this case too, the first zero crossover of the fault signal can be used as a reference point. With the assistance of a known assignment, the value f₁ or f₂ of the oscillation frequency of the laser D1 can be determined from the value of the temperature T₁ or T₂ at temperature sensor N1 (cf. FIG. 14).

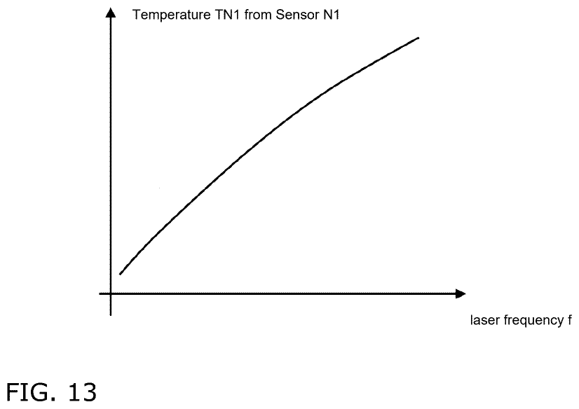

FIG. 13 shows a schematic representation of an association of the temperature of the VBG (G1) with the frequency of the laser according to FIG. 11. In the representation, the temperature T of the temperature sensor N1 (T_{N1}) is plotted against the frequency of the laser G1 (laser frequency f).

### LIST OF REFERENCE SIGNS

D1, D2 Laser
G1 Volume Bragg grating (VBG, frequency-selective element)
E Grating structures (e.g., grating surfaces or planes)
A, B Side surfaces
C Mounting surface
D Top surface
A1 Beam splitter
P1, P3 Reference detectors
P2, P4, P5 measurement detectors
U1 Reference signal (reference detector)
U2 Measurement signal (measurement detector)
E1, E2 Electronic circuits
H1 Grating housing
H2 Module housing
T1, T2, T3 Devices for cooling and/or heating
K1 Calibration table
Y1 Display device
L1, L2, L3 Optical systems
S1, S2 Mirrors
F1 Optical waveguide
R1 Polarizer
N1 Temperature sensor
B1 Optical bench

1. A device for frequency stabilization of a laser comprising a beam path for injecting laser radiation emitted by the laser into a frequency-selective element,
the frequency-selective element is temperature-controlled, and
wherein the frequency-selective element is a volume Bragg grating (VBG) with a plurality of grating structures and, prior to injection of the laser radiation into the VBG via an input facet, a proportion of the laser radiation is branched off into a reference beam and the proportion of the laser radiation injected into the VBG forms a measurement beam.

2. The device according to claim 1, wherein the VBG takes the form of a volume-holographically generated Bragg grating in a photothermorefractive glass.

3. The device according to claim 1, wherein the VBG is arranged in a Littrow configuration.

4. The device according to claim 1, wherein the input facet of the VBG has an angle other than 90° to the beam axis of the incident laser radiation and/or has an angle to the grating structures of the VBG.

5. The device according to claim 1, wherein the VBG comprises a mounting surface, a top surface opposite the mounting surface and two side surfaces connecting the mounting surface and the top surface, wherein a grating vector of the VBG and the top surface are configured parallel to the mounting surface and/or the side surfaces are configured parallel to one another.

6. The device according to claim 5, wherein the VBG takes the form of a parallelepiped and the grating structures of the VBG are in each case arranged perpendicular to the mounting surface, the top surface and the side surfaces of the VBG.

7. The device according to claim 1, wherein the reference beam is branched off at a surface of the VBG or a beam splitter arranged upstream of the VBG.

8. The device according to claim 1, further comprising a reference detector set up to determine an intensity of the reference beam and a measurement detector set up to determine an intensity of the measurement beam, wherein the intensity of the measurement beam is determined after passage through the VBG.

9. The device according to claim 8, further comprising a first electronic circuit for deriving a fault signal from a reference signal of the reference detector and a measurement signal of the measurement detector.

10. The device according to claim 1, wherein the VBG is thermally decoupled from its surroundings by a grating housing.

11. The device according to claim 1, wherein the VBG is arranged with other components in a module housing.

12. The device according to claim 1, wherein at least one device for cooling and/or heating is used for temperature stabilization of the VBG.

13. A method for frequency stabilization of a laser using a device according to claim 1, wherein a fault signal is derived from an intensity of the reference beam and an intensity of the measurement beam after passage through the VBG, and the frequency of the laser is stabilized with the fault signal via a control loop.

14. The method for frequency stabilization of a laser according to claim 13, wherein the laser radiation spectrally filtered by the VBG is reinjected into the laser to form an extended resonator for the laser.

15. A method for measuring the frequency of a laser using a device according to claim 1, wherein a fault signal is derived from an intensity of the reference beam and an intensity of the measurement beam after passage through the VBG, the temperature of the VBG is adjusted with the fault signal via a control loop in such a way that a Bragg frequency of the VBG corresponds to the frequency of the laser except for an optionally selected, signed frequency difference, and the frequency of the laser is determined by way of a known association with the adjusted temperature of the VBG.
